(19) United States
(12) Patent Application Publication
(10) Pub. No.: US 2017/0102484 A1
(43) Pub. Date: Apr. 13, 2017

(54) SELF-CLEANING CAMERA LENS USING PHOTO-CATALYTIC TECHNOLOGY

(71) Applicant: FORD GLOBAL TECHNOLOGIES, LLC, Dearborn, MI (US)

(72) Inventors: Paul Kenneth Dellock, Northville, MI (US); Talat Karmo, Waterford, MI (US); Stuart C. Salter, White Lake, MI (US); Arsen Terjimanian, Troy, MI (US); Michael A. Musleh, Canton, MI (US)

(21) Appl. No.: 14/881,867

(22) Filed: Oct. 13, 2015

(51) Int. Cl. G02B 1/18; C23C 16/40; G02B 1/14; G03B 17/56; G02B 1/04; G02B 5/20

(52) U.S. Cl. CPC G02B 1/18; G02B 1/041; G02B 5/208; G02B 1/14; G03B 17/565; C23C 16/405

(57) ABSTRACT

A self-cleaning camera lens is provided. That self-cleaning camera lens includes a lens body made from a clear plastic material. That lens body incorporates a UV protector. Further, the self-cleaning camera lens includes a silicone hard-coat on a surface of the lens body and a titanium dioxide coating on the silicone hard-coat.

### TECHNICAL FIELD

This document relates generally to the optics field and, more particularly, to a self-cleaning camera lens using photo-catalytic technology.

### BACKGROUND

It has long been known to utilize conventional technology to mold low-cost camera lenses from a clear plastic material such as polycarbonate. Such clear plastic lenses generally exhibit poor UV performance and stability. Further, they scratch fairly easily and due to their hydrophobic nature get dirty quickly.

Current state-of-the-art plastic lenses are coated with a hard-coat to protect from scratches. That hard-coat also contains a UV stabilizer that is similar to those used on automotive headlamps. While this provides some UV protection over several years, UV exposure still tends to turn the lens yellow or cloud the lens, degrading the quality of the camera image and thereby limiting the effective service life of the lens.

This document relates to a new and improved clear plastic lens that provides excellent UV performance, while also being resistant to scratching and abrasion so as to stay clear and avoid image distortion for a prolonged service life. Further, the camera lens includes a titanium dioxide coating so as to be self-cleaning via photocatalytic activity.

More specifically, when UV light shines on titanium dioxide, electrons are released. These electrons interact with water molecules in the air breaking them up into hydroxyl radicals which, while short-lived, are highly reactive uncharged forms of hydroxide ions. The hydroxyl radicals attack organic (carbon-based) molecules from which most dirt is made, breaking apart the chemical bonds of the dirt and oxidizing the larger molecules into smaller, harmless substances such as carbon dioxide and water that are easily washed away from the titanium dioxide treated surface.

### SUMMARY

In accordance with the purposes and benefits described herein, a self-cleaning camera lens is provided. That self-cleaning camera lens comprises a lens body made from a clear plastic material and incorporating a UV protector. The self-cleaning camera lens also includes a silicone hard-coat on a surface of the lens body and a titanium dioxide coating on the silicone hard-coat.

In one possible embodiment, the UV protector is mixed with the clear plastic material prior to the molding of the lens body. In another possible embodiment, the UV protector is infused into an outer skin of the lens body following molding. In any of the embodiments, the UV protector may be selected from a group of materials consisting of benzotriazole, benzophenone, a hindered amine light stabilizer and combinations thereof.

The silicone hard-coat may include a scratch-resistance agent selected from a group consisting of vinyl (mono-, di- and tri-alkoxysilanes), phenyl (mono-, di-, and tri-alkoxysilanes), diphenyldialkoxysilane, vinyltrimethoxysilane, dimethyl phenyl silanol, methyl phenyl (4-trimethyl silyl methyl phenyl) silane, 1,2,3,4-tetrakis (trimethyl silyl)-5-(tris-(trimethylsilyl) silyl) benzene, other silicone-based molecules and mixtures thereof.

The clear plastic material from which the lens is molded may be selected from a group of materials consisting of polycarbonate, acrylic, other clear plastic, and combinations thereof.

In accordance with an additional aspect, a method of manufacturing a camera lens is provided. That method may be broadly described as comprising the steps of: (a) molding a body of the camera lens from a clear plastic material, (b) providing the body with UV protection, (c) coating the body with a silicone hard-coat and (d) coating the silicone hard-coat with a titanium dioxide coating.

In one possible embodiment of the invention, the step of providing the body with UV protection includes mixing a UV protector with the clear plastic material prior to molding. In another possible embodiment, the step of providing the body with UV protection includes infusing the UV protector into an outer skin of the body following molding.

The method may also include the step of cleaning the body following molding and before infusing as well as the step of rinsing the body following infusing.

Still further, the step of coating the body with a silicone hard-coat may include depositing a silicone-based material on the outer skin by means of physical vapor deposition, chemically-enhanced plasma deposition, cathodic arc deposition, sputtering or conventional vacuum coating technology. Further, the coating of the silicone hard-coat with a titanium dioxide coating may include depositing the titanium dioxide coating by means of physical vapor deposition, chemically-enhanced plasma deposition, cathodic arc deposition, sputtering or conventional vacuum coating technology.

In one possible embodiment, the method includes completing the silicone hard-coat coating in a first chamber and completing the titanium dioxide coating in a second chamber. In another possible embodiment, the method includes serially completing the silicone hard-coat coating and the titanium dioxide coating in a single chamber.

In accordance with yet another aspect, a camera is provided incorporating the self-cleaning camera lens described herein.

In the following description, there are shown and described several preferred embodiments of the self-cleaning camera lens. As should be realized, the camera lens is capable of other, different embodiments and its several details are capable of modification in various, obvious aspects all without departing from the camera lens as set forth and described in the following claims. Accordingly, the drawings and descriptions should be regarded as illustrative in nature and not as restrictive.

### BRIEF DESCRIPTION OF THE DRAWING FIGURES

The accompanying drawing figures incorporated herein and forming a part of the specification illustrate several aspects of the self-cleaning camera lens and together with the description serve to explain certain principles thereof.

FIG. 1 is a schematic illustration of a first embodiment of the self-cleaning camera lens that is the subject matter of this document.

FIG. 2 is a schematic illustration of a second embodiment of the self-cleaning camera lens that is the subject matter of this document.

Reference will now be made in detail to the present preferred embodiments of the self-cleaning camera lens, examples of which are illustrated in the accompanying drawing figures.

### DETAILED DESCRIPTION

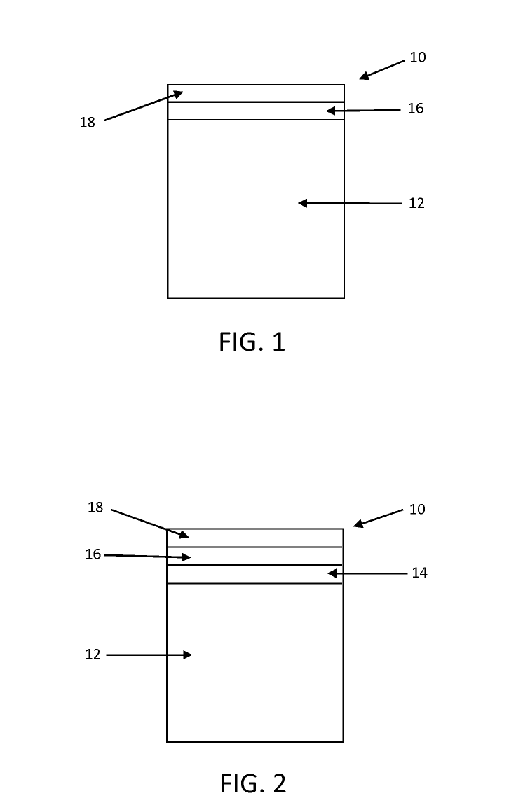

Reference is now made to FIGS. 1 and 2, illustrating two embodiments of a self-cleaning camera lens 10 having a lens body 12 made from a clear plastic material. That clear plastic material may be substantially any clear plastic material suitable for construction of a camera lens including, but not limited to, polycarbonate, acrylic, other clear plastic, and mixtures thereof.

The lens body 12 incorporates a UV protector. In the first illustrated embodiment illustrated in FIG. 1, the UV protector is mixed with the clear plastic material from which the lens body 12 is molded. In the second embodiment illustrated in FIG. 2, the UV protector is infused into an outer skin 14 of the lens body 12. The UV protector may be substantially any UV protector or agent known to those skilled in the art to be useful in the treatment of camera lenses made from plastic material including, but not limited to, benzotriazole, benzophenone, a hindered amine light stabilizer and combinations thereof. The outer skin 14 infused with the UV protector may have a depth of between about 5 microns to about 6 microns.

A silicone hard-coat 16 is provided overlying the lens body 12/outer skin 14. The silicone hard-coat 16 includes a scratch resistance agent selected from a group consisting of vinyl (mono-, di- and tri-alkoxysilanes), phenyl (mono-, di-, and tri-alkoxysilanes), diphenyldialkoxysilane, vinyltrimethoxysilane, dimethyl phenyl silanol, methyl phenyl (4-trimethyl silyl methyl phenyl) silane, 1,2,3,4-tetrakis (trimethyl silyl)-5-(tris-(trimethylsilyl) silyl) benzene, other silicone-based molecules and mixtures thereof.

A titanium dioxide coating 18 is then provided over the hard-coat 16.

In one possible embodiment, the silicone hard-coat 16 has a thickness of between about 1 mμ and about 7 mμ. The titanium dioxide coating 18 has a thickness of between 50 nm and 200 nm. In all embodiments the outer skin 14, hard-coat 16 and titanium dioxide coating 18 are virtually optically clear.

The self-cleaning camera lens 10 is useful in a number of applications including particularly for a camera attached to or carried on a motor vehicle. Such cameras are used as parking aids as well as in accident avoidance systems and in smart forward lighting systems. Advantageously, the camera lens 10 described herein is self-cleaning in nature using photocatalytic technology. More specifically, when exposed to UV light, the titanium dioxide in the titanium dioxide coating 18 releases electrons. These electrons interact with water molecules in the air, breaking those water molecules into hydroxyl radicals which are highly reactive, short-lived, uncharged forms of hydroxide ions. The hydroxyl radicals attack organic (carbon-based) molecules from which most dirt is made, breaking apart the chemical bonds of the dirt and oxidizing larger molecules into smaller, harmless substances such as carbon dioxide and water which may be swept away by air currents and/or rainwater.

More specifically, the hydroxyl radicals make the camera lens 10 super hydrophilic. Accordingly, instead of staying in drops, water molecules spread out evenly across the glass in a very even sheet. Thus, when rain hits the self-cleaning camera lens 10, it spreads across the lens and runs off neatly, evenly washing away any dirt, and the lens dries without any streaks or smears. Thus, the image transmitted through the lens remains clear and distortion-free.

Advantageously, the hard-coat 16 provided between the titanium dioxide coating 18 and the outer skin 14 of the lens body 12 protects the outer skin of the lens body from the oxidizing activity of the hydroxyl radicals produced by the titanium dioxide coating when exposed to UV light. More specifically, the hard-coat contains alternate silicone and oxygen atoms, as (—Si—O—Si—O—). The hydroxyl radicals released by the titanium dioxide as it is subjected to photoelectric effects does not break down the Si—O chain of the hard-coat. Thus, the hard-coat 16 not only protects the lens 10 from scratches and abrasion, but it also protects the lens body and the UV protectors in the lens body (FIG. 1 embodiment) or on the outer skin 14 (FIG. 2 embodiment) from the oxidizing activity. As a consequence, the UV protectors keep the lens clear for distortion-free viewing over a long service life.

The camera lens 10 may be manufactured via a relatively simple and straightforward method that may be broadly described as comprising the steps of: (a) molding the lens body 12 from a clear plastic material, (b) providing the body with UV protection, (c) coating the body with a silicone hard-coat and (d) depositing the silicone hard-coat with a titanium dioxide coating.

For the FIG. 1 embodiment, the step of providing the lens 12 with UV protection includes mixing a UV protector with the clear plastic material prior to molding. In contrast, for the FIG. 2 embodiment, the step of providing the lens 12 with UV protection includes infusing a UV protector into an outer skin 14 of the body 12. As previously noted, the UV protector may comprise, for example, benzotriazole, benzophenone, a hindered amine light stabilizer and combinations thereof. It should be appreciated, however, that this list is not limiting in nature and is only provided as an example of the UV protectors that may be utilized.

The method may also include the steps of (a) cleaning the body 12 following molding and before infusing and (b) rinsing the body following infusing. The silicone hard-coat 16 may be provided by depositing a silicone-based material on the outer skin by means of physical vapor deposition, chemically-enhanced plasma deposition, cathodic arc deposition, sputtering or conventional vacuum-coating technology. Similarly, the titanium dioxide coating 18 may be provided by depositing the titanium dioxide by means of physical vapor deposition, chemically-enhanced plasma deposition, cathodic arc deposition, sputtering or conventional vacuum-coating technology. In one possible embodiment, the silicone hard-coat coating step is completed in a first chamber while the titanium dioxide coating step is completed in a second chamber. In another embodiment, the two coating steps are serially completed in the same chamber.

In summary, the self-cleaning camera lens 10 described herein provides a number of benefits and advantages. The lens 10 includes three unique optically clear coatings: the UV infused outer skin 14, the hard-coat 16 and the titanium dioxide coating 18, in a prescribed sequence to improve UV protection, improve scratch resistance and provide a self-cleaning surface. Advantageously, the self-cleaning surface significantly reduces the amount dirt on the camera lens 10 especially after it rains.

The infused or plasma-deposited UV inhibitor or protector is provided with a higher concentration than what is typically found in coatings or can be added to a base substrate for improved UV performance. Further, the silicone hard-coat 16 deposited with plasma deposition is more consistent in thickness than conventional coatings, reducing optical distortion. Further, it should be appreciated that all the coating methods are relatively low-cost and do not require curing steps.

The foregoing has been presented for purposes of illustration and description. It is not intended to be exhaustive or to limit the embodiments to the precise form disclosed. Obvious modifications and variations are possible in light of the above teachings. All such modifications and variations are within the scope of the appended claims when interpreted in accordance with the breadth to which they are fairly, legally and equitably entitled.

What is claimed:

1. A self-cleaning camera lens, comprising:
a lens body made from a clear plastic material and incorporating a UV protector;
a silicone hard-coat on a surface of said lens body; and
a titanium dioxide coating on said silicone hard-coat.

2. The self-cleaning camera lens of claim 1, wherein said UV protector is mixed into said clear plastic material.

3. The self-cleaning camera lens of claim 1, wherein said UV protector is infused into an outer skin of said lens body.

4. The self-cleaning camera lens of claim 3, wherein said UV protector is selected from a group consisting of benzotriazole, benzophenone, a hindered amine light stabilizer and combinations thereof.

5. The self-cleaning camera lens of claim 4, wherein said outer skin has a depth of between about 5 microns to about 6 microns.

6. The self-cleaning camera lens of claim 5, wherein said silicone hard-coat includes a scratch resistance agent selected from a group consisting of vinyl (mono-, di- and tri-alkoxysilanes), phenyl (mono-, di- and tri-alkoxysilanes), diphenyldialkoxysilane, vinyltrimethoxysilane, dimethyl phenyl silanol, methyl phenyl (4-trimethyl silyl methyl phenyl) silane, 1,2,3,4-tetrakis (trimethyl silyl)-5-(tris-(trimethylsilyl) silyl) benzene other silicone-based molecules and mixtures thereof.

7. The self-cleaning camera lens of claim 6, wherein said clear plastic material is selected from a group consisting of polycarbonate, acrylic, other clear plastic and combinations thereof.

8. The self-cleaning camera lens of claim 1, wherein said UV protector is selected from a group consisting of benzotriazole, benzophenone, a hindered amine light stabilizer and combinations thereof.

9. The self-cleaning camera lens of claim 1, wherein said silicone hard-coat includes a scratch resistance agent selected from a group consisting of vinyl (mono-, di- and tri-alkoxysilanes), phenyl (mono-, di- and tri-alkoxysilanes), diphenyldialkoxysilane, vinyltrimethoxysilane, dimethyl phenyl silanol, methyl phenyl (4-trimethyl silyl methyl phenyl) silane, 1,2,3,4-tetrakis (trimethyl silyl)-5-(tris-(trimethylsilyl) silyl) benzene, other silicone-based molecules and mixtures thereof.

10. The self-cleaning camera lens of claim 1, wherein said clear plastic material is selected from a group consisting of polycarbonate, acrylic, other clear plastic and combinations thereof.

11. A method of manufacturing a camera lens, comprising:
molding a body of said camera lens from a clear plastic material;
providing said body with UV protection;
coating said body with a silicone hard-coat; and
coating said silicon hard-coat with a titanium dioxide coating.

12. The method of claim 11, wherein providing said body with UV protection includes mixing a UV protector with said clear plastic material prior to molding.

13. The method of claim 11, wherein providing said body with UV protection includes infusing a UV protector into an outer skin of said body.

14. The method of claim 13, including (a) cleaning said body following molding and before infusing and (b) rinsing said body following infusing.

15. The method of claim 14, wherein coating said body with a silicone hard-coat includes depositing a silicone-based material on said outer skin by means of physical vapor deposition, chemically enhanced plasma deposition, cathodic arc deposition, sputtering or conventional vacuum coating technology.

16. The method of claim 15, wherein coating said silicone hard-coat with a titanium dioxide coating includes depositing said titanium dioxide coating by means of physical vapor deposition, chemically enhanced plasma deposition, cathodic arc deposition, sputtering or conventional vacuum coating technology.

17. The method of claim 16, including completing said silicone hard-coat coating in a first chamber and completing said titanium dioxide coating in a second chamber.

18. The method of claim 16, including serially completing said silicone hard-coat coating and said titanium dioxide coating in a single chamber.

19. A camera incorporating said self-cleaning camera lens of claim 1.

20. A camera incorporating said self-cleaning camera lens of claim 3.
